(19) United States
(12) Patent Application Publication
(10) Pub. No.: US 2025/0341677 A1
(43) Pub. Date: Nov. 6, 2025

(54) LOW FREQUENCY IMPRINT FOR GRAYSCALE OPTICAL DEVICE FABRICATION

(71) Applicant: Applied Materials, Inc., Santa Clara, CA (US)

(72) Inventors: Yingdong LUO, Newark, CA (US); Zhengping YAO, Cupertino, CA (US); Daihua ZHANG, Los Altos, CA (US); Yingchao ZHANG, Santa Clara, CA (US); Xiaopei DENG, San Jose, CA (US); Rami HOURANI, Santa Clara, CA (US); Ludovic GODET, Sunnyvale, CA (US)

(21) Appl. No.: 19/122,019

(22) PCT Filed: Jan. 17, 2024
(86) PCT No.: PCT/US2024/011850

§ 371 Date: Apr. 17, 2025

Related U.S. Application Data
(60) Provisional application No. 63/480,139, filed on Jan. 17, 2023.

(51) Int. Cl. G02B 6/136; G02B 6/12

(52) U.S. Cl. CPC G02B 6/136; G02B 2006/12107

(57) ABSTRACT

Embodiments described herein relate to methods for forming waveguides with gratings of structures having depths distributions, method includes disposing a resist material over areas of a device material or a substrate corresponding to gratings of structures to be formed having depth distributions, imprinting a stamp into the resist material over areas, the stamp having a positive pattern of the depth distribution, the imprinting the stamp and curing the resist material forms a patterned resist over the areas, releasing the stamp, etching the patterned resist and one of the device material or the substrate to form the depth distributions in the device material or the substrate, and forming the structures in the areas having the depth distributions to form the gratings.

### BACKGROUND

### Field

Embodiments of the present disclosure generally relate to waveguide. More specifically, embodiments described herein provide for methods for forming waveguides with gratings having depths distributions.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as optical device eyepieces to display a virtual reality environment that replaces an actual environment.

Augmented reality, however, enables an experience in which a user can still see through the optical device eyepieces of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

According what is needed in the art are methods of forming waveguides with gratings having depths distributions.

### SUMMARY

In one embodiment, a method is provided. The method includes disposing a resist material over areas of a device material or a substrate corresponding to gratings of structures to be formed having depth distributions, imprinting a stamp into the resist material over areas, the stamp having a positive pattern of the depth distribution, the imprinting the stamp and curing the resist material forms a patterned resist over the areas, releasing the stamp, etching the patterned resist and one of the device material or the substrate to form the depth distributions in the device material or the substrate, and forming the structures in the areas having the depth distributions to form the gratings.

In another embodiment, a method is provided. The method includes disposing a resist material on a positive pattern of a stamp, the positive pattern corresponding to depth distributions of gratings of structures to be formed, flipping and disposing the stamp such that the resist material is disposed on areas of a device material or a substrate corresponding to the gratings of the structures to be formed having depth distributions, curing to form a patterned resist over the areas, releasing the stamp, etching the patterned resist and one of the device material or the substrate to form the depth distributions in the device material or the substrate, and forming the structures in the areas having the depth distributions to form the gratings.

In yet another embodiment, a method is provided. The method includes disposing a resist material on a pattered hardmask, the pattered hardmask disposed over a device material or a substrate, resist material is disposed over areas of the device material or the substrate corresponding to gratings of structures to be formed having depth distributions, and imprinting a stamp into the resist material over areas, the stamp having a positive pattern of the depth distribution, the imprinting the stamp and curing the resist material forms a patterned resist over the areas, releasing the stamp, and etching the patterned resist and one of the device material or the substrate to form gratings of structures having the depth distributions in the device material or the substrate

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a perspective, frontal view of a waveguide according to embodiments.

FIG. 2A is a cross-sectional view of a portion of a waveguide of a first configuration according to embodiments.

FIG. 2B is a cross-sectional view of a portion of a waveguide of a second configuration according to embodiments.

FIGS. 3A-3C are schematic, cross-sectional views of a substrate during a first method according to embodiments.

FIG. 4A is a schematic, cross-sectional view of a stamp during a second method according to embodiments.

FIGS. 4B-4D are schematic, cross-sectional views of a substrate during a second method according to embodiments.

FIGS. 5A-5D are schematic, cross-sectional views of a substrate during a third method according to embodiments.

FIGS. 6A-6D are schematic, cross-sectional views of stamps according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to methods for forming waveguides with gratings of structures having depths distributions.

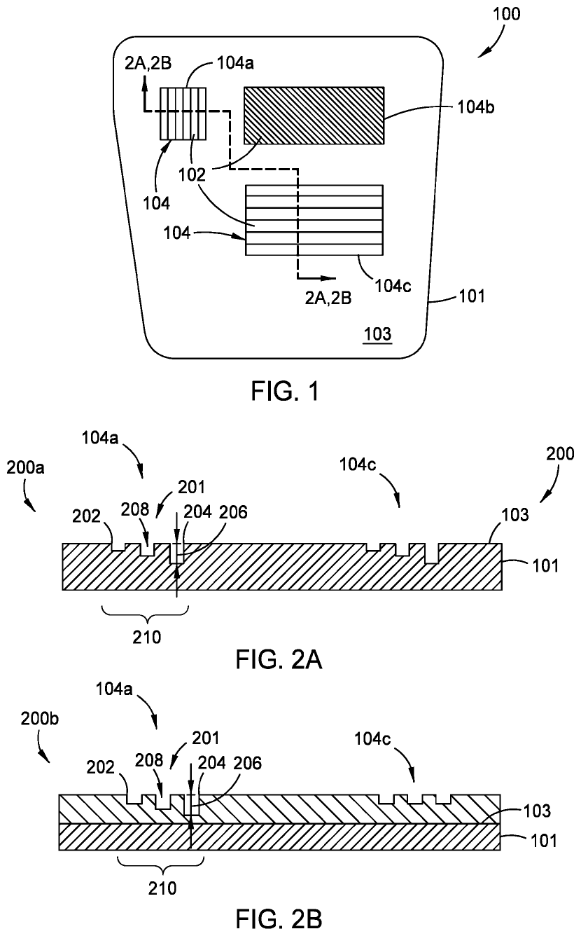

FIG. 1 is a perspective, frontal view of a waveguide 100. It is to be understood that the waveguide 100 described herein is an exemplary waveguide and that other waveguides may be used with or modified to accomplish aspects of the present disclosure. The waveguide 100 includes a plurality of structures 102. The structures 102 may be disposed over, under, or on (FIG. 2B) a surface 103 of a substrate 101, or disposed in the substrate 101 (FIG. 2A). The structures 102 are nanostructures have a sub-micron critical dimension, e.g., a width less than 1 micrometer. Regions of the structures 102 correspond to one or more gratings 104. In one embodiment, which can be combined with other embodiments described herein, the waveguide 100 includes at least a first grating 104a corresponding to an input coupling grating and a third grating 104c corresponding to an output coupling grating. In another embodiment, which can be combined with other embodiments described herein, the waveguide 100 further includes a second grating 104b. The second grating 104b corresponds to a pupil expansion grating or a fold grating. The structures 102 of the gratings 104 must be tuned in order to control the intensity of the beams to modulate a field of view of the virtual image produced from the microdisplay from a user's perspective and increase a viewing angle from which a user can view the virtual image. To tune the gratings 104 the structures 102 have depths distributions.

FIG. 2A is a cross-sectional view of a portion of a waveguide 100 of a first configuration 200a according to embodiments. FIG. 2B is a cross-sectional view of a portion of the waveguide 100 of a second configuration 200b according to embodiments.

The waveguide 100 of the first configuration 200a includes gratings 104 with the structures 102 disposed in the substrate 101. The waveguide 100 of the second configuration 200b includes gratings 104 with the structures 102 disposed on or over the substrate 101. The structures 102 of the second configuration 200b include a device material 211. The substrate 101 includes of any suitable material, including, but not limited to, amorphous dielectrics, non-amorphous dielectrics, crystalline dielectrics, silicon-containing materials, polymers, or combinations thereof. In one embodiment, which can be combined with other embodiments described herein, the substrate 101 consists of one or more of silicon (Si), silicon dioxide (SiO₂), silicon carbide (SiC), fused silica, diamond, or quartz materials. In another embodiment, which can be combined with other embodiments described herein, the substrate 101 consists of one or more of nitrogen, titanium, niobium, lanthanum, zirconium, or yttrium containing-materials. The device material 211 includes, but is not limited to, silicon carbide (SiC), silicon oxycarbide (SiOC), titanium dioxide (TiO₂), silicon dioxide (SiO₂), vanadium (IV) oxide (VOx), aluminum oxide (Al₂O₃), aluminum-doped zinc oxide (AZO), indium tin oxide (ITO), tin dioxide (SnO₂), zinc oxide (ZnO), tantalum pentoxide (Ta₂O₅), silicon nitride (Si₃N₄), zirconium dioxide (ZrO₂), niobium oxide (Nb₂O₅), cadmium stannate (Cd₂SnO₄), silicon mononitride (SiN), silicon oxynitride (SiON), barium titanate (BaTiO₃), diamond like carbon (DLC), hafnium (IV) oxide (HfO₂), lithium niobate (LiNbO₃), silicon carbon-nitride (SiCN), or combinations thereof.

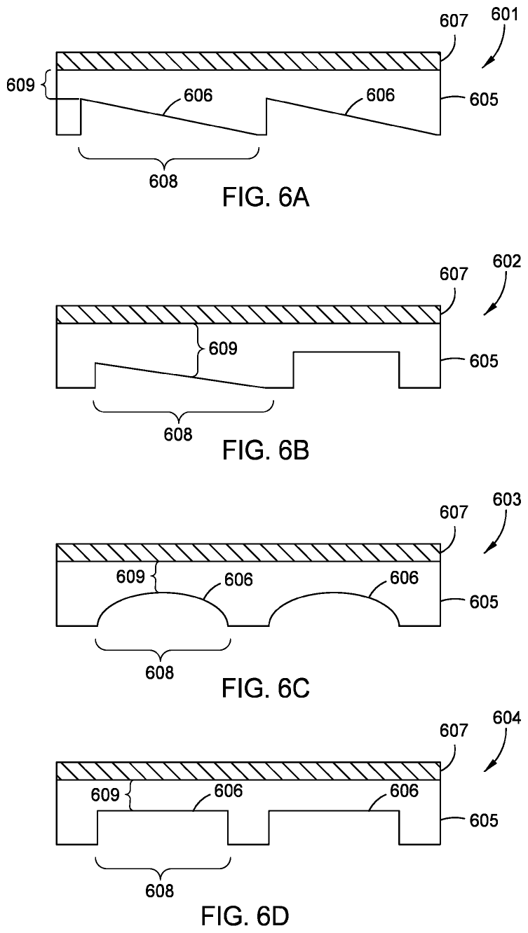

The gratings 104 have a depth distribution 201 from a first end 202 to a second end 204. The depth distribution 201 corresponds to a change in depth 206 of a channel 208 between adjacent structures 102. FIGS. 6A-6D are schematic, cross-sectional views of stamps according to embodiments. In one embodiment, which can be combined with other embodiments described herein, the depth distribution 201 is linear as the depths 206 of the channels 208 change linearly from the first end 202 to the second end 204. The methods 300-500 utilize a first stamp 601 to form two gratings 104, such as the first grating 104a and the third grating 104c, with have the depth distribution 201 that is linear. As shown in FIG. 6A, a stamp structure 605 of the first stamp 601 includes imprint portions 606 that are a positive (i.e., corresponding to) of the depth distribution 201 that is linear. The methods 300-500 utilize a second stamp 602 to form one grating 104, such as the first grating 104a, with the depth distribution 201 that is linear and another grating 104, such as the third grating 104c, with the depth distribution 201 that is uniform. As shown in FIG. 6B, the stamp structure 605 of a second stamp 602 includes one imprint portion 606 that is a positive of the depth distribution 201 that is linear and another imprint portion 606 that corresponds to the depth distribution 201 that is uniform. As shown in FIG. 2B, the third grating 104c has the depth distribution 201 that is uniform, i.e., the depth distribution 201 depths 206 of the channels 208 are the same from the first end 202 to the second end 204. The methods 300-500 utilize a fourth stamp 604 that includes imprint portions 606 that are uniform for two gratings 104 with the depth distribution 201 that is uniform. The methods 300-500 utilize a third stamp 603 that includes imprint portions 606 that are a positive of a depth distribution 201 that is non-linear such that the gratings 104 have a depth distribution 201 that is non-linear from the first end 202 to the second end 204.

As shown in FIGS. 6A-6D, the stamp structure 605 is coupled to a stamp substrate 607. The stamp structure 605 includes, but is not limited to, polydimethylsiloxane (PDMS), UV-curable acrylate, epoxy, polyurethane, or combinations thereof. The stamp substrate 607 includes, but is not limited to, polyethylene terephthalate (PET), glass, silica, or combinations thereof. The stamp structure 605 and the stamp substrate 607 are semi-transparent such that a resist material may be cured by exposure to ultraviolet (UV) light. The stamp substrate 607 may have a thickness of about 10 μm to about 5 mm. A portion width 608 of the imprint portions 606 is about 100 μm to about 100 cm to results in gratings 104 having a grating width 210 of about 100 μm to about 100 cm. A distance from the stamp structure 605 to the stamp substrate 607 is less than 1 mm. The gratings 104 may include any combination of linear, non-linear, or uniform depth distribution 201 in order to control the intensity of the beams to modulate a field of view of the virtual image produced from the microdisplay from a user's perspective and increase a viewing angle from which a user can view the virtual image.

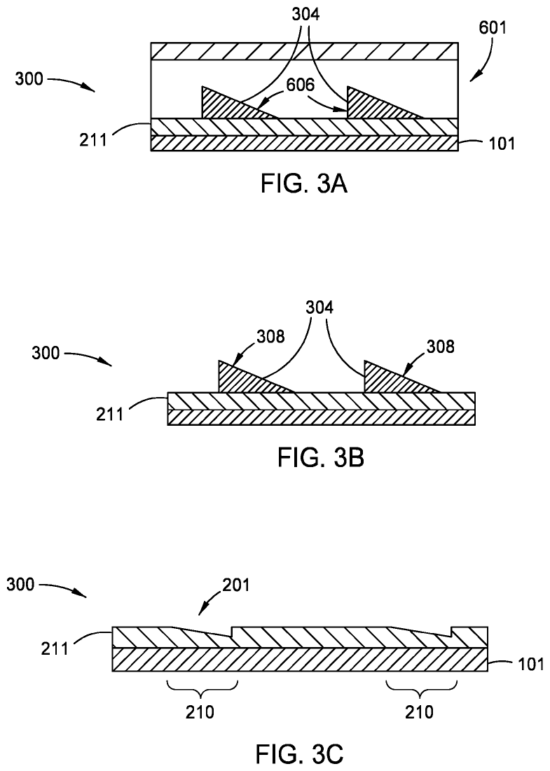

FIGS. 3A-3C are schematic, cross-sectional views of a substrate 100 during a first method 300 of forming a waveguide 100 having gratings 104 depth distributions 201. In a first operation of the first method 300, a patterned resist 306 having a negative pattern 308 is formed. The negative pattern 308 is the inverse of the stamp structure 605. In some embodiments, the negative pattern 308 is formed over the 103 of the substrate 101. In other embodiments, the negative pattern 308 is formed on the surface 103 of the substrate 101. The negative pattern 108 is a negative of the depth distributions 201. The depth distribution 201 may be any linear, non-linear, or uniform distribution corresponding to the stamp structure 605. In one embodiment of the first operation, as shown in FIG. 3A, a stamp, such as the first stamp 601, is imprinted on a resist material 304 disposed on or over the surface 103 of the substrate 100. In other embodiments, the second stamp 602, third stamp 603, or the fourth stamp 605 is used. The resist material 304 is deposited via inkjet printing or spin coating. The resist material 304 is cured to form the patterned resist 306 having the negative pattern 308. After the patterned resist 306 is cured, the stamp is released, as shown in FIG. 3B. In a second operation, the patterned resist 306 and the device material 211 or the substrate 101 are etched to form the waveguide 100. The waveguide 100 has the depth distributions 201 at areas 210 corresponding to the gratings 104 as shown in FIG. 3C. The gratings 104 are formed via disposing a hardmask over the substrate 101 and disposing a photoresist over the substrate 101. The photoresist is pattered according to a desired grating pattern to expose the hardmask. The hardmask is then etched to expose the device material 211 or the substrate 101. The device material 211 or the substrate 101 is then etched to form the gratings 104. The photoresist and hardmask are then removed.

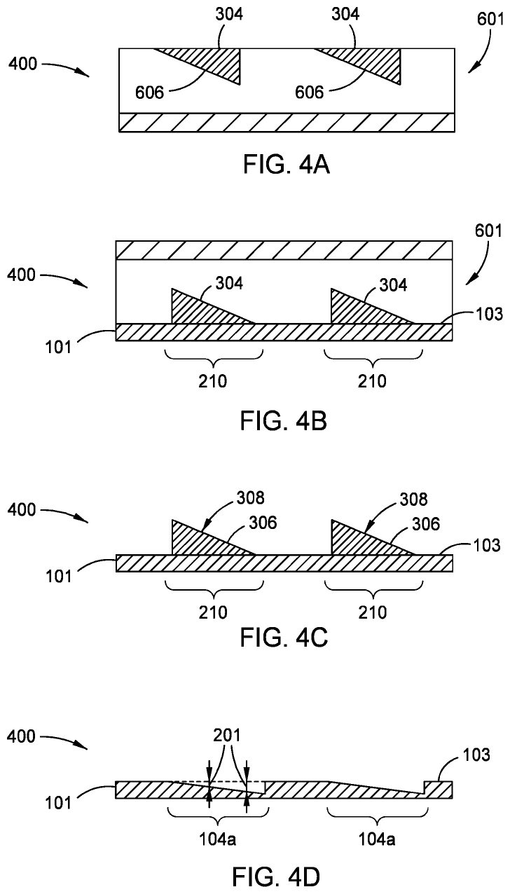

FIG. 4A is a schematic, cross-sectional view of a stamp. The stamp may be the first stamp 601. In other embodiments, the second stamp 602, third stamp 603, or the fourth stamp 605 is used. FIGS. 4B-4D are schematic, cross-sectional views of a substrate 101 during a second method 400 of forming the waveguide 100 having depth distributions 201. In a first operation of the second method 400, a resist material 304 disposed on a positive pattern of the imprint portions 606 of the stamp. In a second operation, the stamp is flipped and disposed on or over the surface 103 of the substrate 100. In a third operation, the resist material 304 is cured to form the patterned resist 306 having the negative pattern that is the inverse of the stamp structure 605. In one embodiment of the third operation, the resist material 304 is cured before the stamp is flipped. In another embodiment of the third operation, the resist material 104 is cured after the stamp is flipped and disposed on or over the surface 103 of the substrate 100. In a fourth operation, the substrate 101 or the device material 211 with the patterned resist 306 is etched to form the depths distributions 201 at areas 210 corresponding to the gratings 104. The gratings 104 are formed via disposing a hardmask over the substrate 101 and disposing a photoresist over the substrate 101. The photoresist is pattered according to a desired grating pattern to expose the hardmask. The hardmask is then etched to expose the device material 211 or the substrate 101. The device material 211 or the substrate 101 is then etched to form the gratings 104. The photoresist and hardmask are then removed.

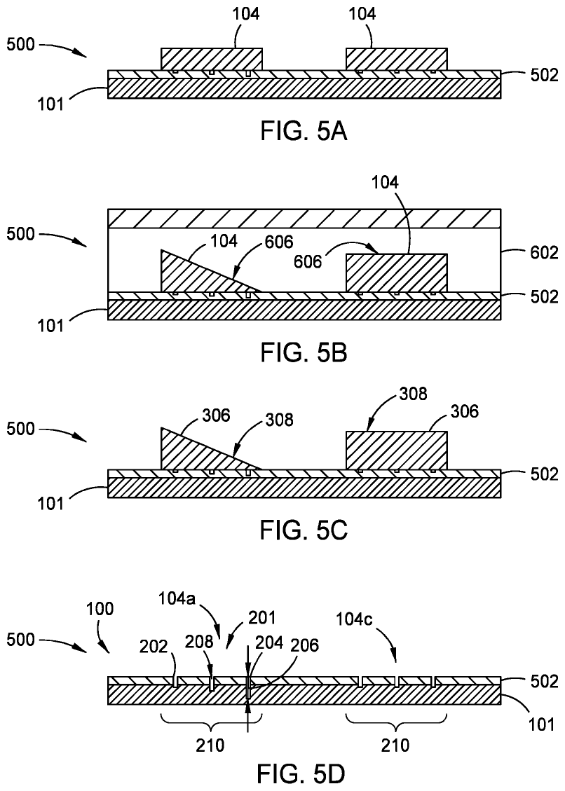

FIGS. 5A-5D are schematic, cross-sectional views of a substrate 101 during a third method of forming the waveguide 100 having gratings with depth distributions 201. In a first operation of the third method, a resist material 304 is disposed on a patterned hardmask 502. The patterned hardmask 502 is disposed on or over a surface 103 of the substrate 101. The patterned hardmask 502 exposed the device material 211 or the substrate 101 to be etched to form the structures 102 of each of the gratings 104 . . . . In a second operation of the third method 500, a patterned resist 306 having a negative pattern 308 is formed. The negative pattern 308 is the inverse of the stamp structure 605. In some embodiments, the negative pattern 308 is formed over the 103 of the substrate 101. In other embodiments, the negative pattern 308 is formed on the surface 103 of the substrate 101. The negative pattern 108 is a negative of the depth distributions 201. The depth distribution 201 may be any linear, non-linear, or uniform distribution corresponding to the stamp structure 605. The resist material 104 is cured to form the patterned resist 306 having the negative pattern 308. After the patterned resist 306 is formed, the stamp 400 is released, as shown in FIG. 5C. In a second operation, the device material 211 or the substrate 101 with the patterned resist 306 is etched to gratings 104 with structures 102 having depth distributions 210. The patterned hardmask 502 is removed.

Embodiments described herein relate to methods for forming waveguides with gratings of structures having depths distributions. Each of the method utilize a stamp having a stamp structure including imprint portions that are a positive (i.e., corresponding to) of the depth distribution. The positive pattern of the imprint portions are designed to correspond to the depth distribution. The imprinted resist having the negative pattern controls the etch rate such the device material or the substrate includes the depth distributions.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
disposing a resist material over areas of a device material or a substrate corresponding to gratings of structures to be formed having depth distributions;
imprinting a stamp into the resist material over areas, the stamp having a positive pattern of the depth distribution, the imprinting the stamp and curing the resist material forms a patterned resist over the areas;
releasing the stamp;
etching the patterned resist and one of the device material or the substrate to form the depth distributions in the device material or the substrate; and
forming the structures in the areas having the depth distributions to form the gratings.

2. The method of claim 1, wherein the gratings include a first grating or a second grating, wherein:
a first depth distribution of the first grating is linear, non-linear, or uniform; and
a second depth distribution of the second grating is linear, non-linear, or uniform.

3. The method of claim 2, wherein the first depth distribution and the second depth distribution are different from each other.

4. The method of claim 1, wherein a portion width of imprint portions of the stamp is about 100 μm to about 100 cm such that the gratings having a grating width of about 100 μm to about 100 cm.

5. The method of claim 1, wherein the substrate comprises silicon (Si), silicon dioxide (SiO₂), silicon carbide (SiC), fused silica, diamond, quartz nitrogen, titanium, niobium, lanthanum, zirconium, yttrium, or combinations thereof.

6. The method of claim 1, wherein the device material comprises silicon carbide (SiC), silicon oxycarbide (SiOC), titanium dioxide (TiO₂), silicon dioxide (SiO₂), vanadium (IV) oxide (VOx), aluminum oxide (Al₂O₃), aluminum-doped zinc oxide (AZO), indium tin oxide (ITO), tin dioxide (SnO₂), zinc oxide (ZnO), tantalum pentoxide (Ta₂O₅), silicon nitride (Si₃N₄), zirconium dioxide (ZrO₂), niobium oxide (Nb₂O₅), cadmium stannate (Cd₂SnO₄), silicon mononitride (SiN), silicon oxynitride (SiON), barium titanate (BaTiO₃), diamond like carbon (DLC), hafnium (IV) oxide (HfO₂), lithium niobate (LiNbO₃), silicon carbon-nitride (SiCN), or combinations thereof.

7. A method, comprising:
disposing a resist material on a positive pattern of a stamp, the positive pattern corresponding to depth distributions of gratings of structures to be formed;
flipping and disposing the stamp such that the resist material is disposed on areas of a device material or a substrate corresponding to the gratings of the structures to be formed having depth distributions;
curing to form a patterned resist over the areas;
releasing the stamp;
etching the patterned resist and one of the device material or the substrate to form the depth distributions in the device material or the substrate; and
forming the structures in the areas having the depth distributions to form the gratings.

8. The method of claim 7, wherein the gratings include a first grating or a second grating, wherein:
a first depth distribution of the first grating is linear, non-linear, or uniform; and
a second depth distribution of the second grating is linear, non-linear, or uniform.

9. The method of claim 8, wherein the first depth distribution and the second depth distribution are different from each other.

10. The method of claim 7, wherein a portion width of imprint portions of the stamp is about 100 μm to about 100 cm such that the gratings having a grating width of about 100 μm to about 100 cm.

11. The method of claim 7, wherein the substrate comprises silicon (Si), silicon dioxide (SiO₂), silicon carbide (SiC), fused silica, diamond, quartz nitrogen, titanium, niobium, lanthanum, zirconium, yttrium, or combinations thereof.

12. The method of claim 7, wherein the device material comprises silicon carbide (SiC), silicon oxycarbide (SiOC), titanium dioxide (TiO₂), silicon dioxide (SiO₂), vanadium (IV) oxide (VOx), aluminum oxide (Al₂O₃), aluminum-doped zinc oxide (AZO), indium tin oxide (ITO), tin dioxide (SnO₂), zinc oxide (ZnO), tantalum pentoxide (Ta₂O₅), silicon nitride (Si₃N₄), zirconium dioxide (ZrO₂), niobium oxide (Nb₂O₅), cadmium stannate (Cd₂SnO₄), silicon mononitride (SiN), silicon oxynitride (SiON), barium titanate (BaTiO₃), diamond like carbon (DLC), hafnium (IV) oxide (HfO₂), lithium niobate (LiNbO₃), silicon carbon-nitride (SiCN), or combinations thereof.

13. The method of claim 7, wherein resist material is deposited via inkjet printing or spin coating.

14. A method, comprising:
disposing a resist material on a pattered hardmask, the pattered hardmask disposed over a device material or a substrate, resist material is disposed over areas of the device material or the substrate corresponding to gratings of structures to be formed having depth distributions; and
imprinting a stamp into the resist material over areas, the stamp having a positive pattern of the depth distribution, the imprinting the stamp and curing the resist material forms a patterned resist over the areas;
releasing the stamp; and
etching the patterned resist and one of the device material or the substrate to form gratings of structures having the depth distributions in the device material or the substrate.

15. The method of claim 14, wherein the gratings include a first grating or a second grating, wherein:
a first depth distribution of the first grating is linear, non-linear, or uniform; and
a second depth distribution of the second grating is linear, non-linear, or uniform.

16. The method of claim 15, wherein the first depth distribution and the second depth distribution are different from each other.

17. The method of claim 14, wherein a portion width of imprint portions of the stamp is about 100 μm to about 100 cm such that the gratings having a grating width of about 100 μm to about 100 cm.

18. The method of claim 14, wherein the substrate comprises silicon (Si), silicon dioxide (SiO₂), silicon carbide (SiC), fused silica, diamond, quartz nitrogen, titanium, niobium, lanthanum, zirconium, yttrium, or combinations thereof.

19. The method of claim 14, wherein the device material comprises silicon carbide (SiC), silicon oxycarbide (SiOC), titanium dioxide (TiO₂), silicon dioxide (SiO₂), vanadium (IV) oxide (VOx), aluminum oxide (Al₂O₃), aluminum-doped zinc oxide (AZO), indium tin oxide (ITO), tin dioxide (SnO₂), zinc oxide (ZnO), tantalum pentoxide (Ta₂O₅), silicon nitride (Si₃N₄), zirconium dioxide (ZrO₂), niobium oxide (Nb₂O₅), cadmium stannate (Cd₂SnO₄), silicon mononitride (SiN), silicon oxynitride (SiON), barium titanate (BaTiO₃), diamond like carbon (DLC), hafnium (IV) oxide (HfO₂), lithium niobate (LiNbO₃), silicon carbon-nitride (SiCN), or combinations thereof.

20. The method of claim 14, wherein the pattered hardmask exposes the device material or the substrate.
